(19) United States
(12) Patent Application Publication
(10) Pub. No.: US 2024/0234209 A1
(43) Pub. Date: Jul. 11, 2024

(54) CONTACT RESISTANCE REDUCTION BY INTEGRATION OF MOLYBDENUM WITH TITANIUM

(71) Applicant: Applied Materials, Inc., Santa Clara, CA (US)

(72) Inventors: Avgerinos V. Gelatos, Scotts Valley, CA (US); Yang Hu, Sunnyvale, CA (US); Thomas Anthony Empante, San Jose, CA (US); Gaurav Thareja, Santa Clara, CA (US); Joung Joo Lee, San Jose, CA (US); Shi You, San Jose, CA (US); Pranav Ramesh, Mountain View, CA (US); Chi H. Ching, Mountain View, CA (US); Nicolas Breil, Alviso, CA (US)

(73) Assignee: Applied Materials, Inc., Santa Clara, CA (US)

(21) Appl. No.: 18/544,812

(22) Filed: Dec. 19, 2023

Related U.S. Application Data
(60) Provisional application No. 63/437,168, filed on Jan. 5, 2023.

(51) Int. Cl. H01L 21/768; H01L 21/8238; H01L 23/528; H01L 23/532; H01L 27/092; H01L 29/417; H01L 29/45

(52) U.S. Cl. CPC H01L 21/76889; H01L 21/823871; H01L 23/5283; H01L 23/53266; H01L 27/0922; H01L 29/41725; H01L 29/456

(57) ABSTRACT

Methods for forming a semiconductor structure and semiconductor structures are described. The method comprises patterning a substrate to form a first opening and a second opening, the substrate comprising an n transistor and a p transistor, the first opening over the n transistor and the second opening over the p transistor. The substrate is pre-cleaned. A molybdenum silicide (MoSi) layer is deposited on one or more of the p transistor and the n transistor. A titanium silicide (TiSi) layer is formed on the n transistor and the p transistor. A capping layer may be formed on the titanium silicide (TiSi) layer. The method may be an integrated method performed in a processing chamber without breaking vacuum.

### CROSS-REFERENCE TO RELATED APPLICATIONS

This application claims priority to United States Provisional Application No. 63/437,168, filed Jan. 5, 2023, the entire disclosure of which is hereby incorporated by reference herein.

### TECHNICAL FIELD

Embodiments of the present disclosure pertain to the field of semiconductor devices and semiconductor device manufacturing. More particularly, embodiments of the disclosure relate to methods of reducing contact resistance for both NMOS and PMOS by integrating molybdenum process with titanium.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure and to reduce contact resistance. Examples of transistor device structures include a planar structure, a fin field effect transistor (finFET) structure, and a gate all around (GAA) structure. Logic gate performance is related to the characteristics of the materials used as well as the thickness and area of the structural layers. However, as some gate characteristics are adjusted to accommodate device scaling, challenges arise.

As we move into advanced modes below the 2 nm node, there is a desire to improve speed and drive current of devices through reduction of contact resistance. Accordingly, there is a need for improved methods of reducing contact resistance.

### SUMMARY

One or more embodiments of the disclosure are directed to a method of forming a semiconductor structure. The method comprises: depositing a molybdenum silicide (MoSi) layer on one or more of a p transistor and an n transistor of a substrate, the substrate comprising an n transistor and the p transistor and having a first opening over the n transistor and a second opening over the p transistor; optionally, in-situ annealing the substrate in an atmosphere of hydrogen (H₂); forming a titanium silicide (TiSi) layer on the n transistor and on the p transistor; and forming a capping layer on the titanium silicide (TiSi) layer.

Another embodiment of the disclosure is directed to a method of forming a semiconductor structure. In one or more embodiments, the method comprises: pre-cleaning a substrate, the substrate comprising an n transistor and a p transistor, a first opening over the n transistor and a second opening over the p transistor; depositing a molybdenum silicide (MoSi) layer on the p and on the n transistor; optionally, in-situ annealing the substrate in an atmosphere of hydrogen (H₂); forming a titanium silicide (TiSi) layer on the molybdenum silicide (MoSi) layer; forming a capping layer on the titanium silicide (TiSi) layer; and depositing a gap fill material in the first opening and in the second opening.

Further embodiments of the disclosure are directed to a semiconductor structure. The semiconductor structure comprises: an n transistor and a p transistor; a molybdenum silicide (MoSi) layer on one or more of the p transistor and the n transistor; a titanium silicide (TiSi) layer on the p transistor and on the n transistor; a capping layer on the titanium silicide (TiSi) layer; and a gap fill material.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method according to one or more embodiments of the disclosure;

FIG. 2A illustrates a semiconductor structure in accordance with one or more embodiments of the disclosure;

FIG. 2B illustrates a semiconductor structure in accordance with one or more embodiments of the disclosure;

FIG. 2C illustrates a semiconductor structure in accordance with one or more embodiments of the disclosure;

FIG. 2D illustrates a semiconductor structure in accordance with one or more embodiments of the disclosure;

FIG. 2E illustrates a semiconductor structure in accordance with one or more embodiments of the disclosure;

FIG. 3 illustrates a process flow diagram of a method according to one or more alternative embodiments of the disclosure;

FIG. 4A illustrates a semiconductor structure in accordance with one or more embodiments of the disclosure;

FIG. 4B illustrates a semiconductor structure in accordance with one or more embodiments of the disclosure;

FIG. 4C illustrates a semiconductor structure in accordance with one or more embodiments of the disclosure;

FIG. 4D illustrates a semiconductor structure in accordance with one or more embodiments of the disclosure;

FIG. 4E illustrates a semiconductor structure in accordance with one or more embodiments of the disclosure;

FIG. 5 illustrates a schematic top-view diagram of an example multi-chamber processing system according to one or more embodiments; and

FIG. 6 is a bar chart of contact resistance results according to the Examples.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

Additionally, the term “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, dielectric materials, other conductive materials, or combinations thereof, depending on the application. In some embodiments, the substrate comprises silicon (Si), ruthenium (Ru), cobalt (Co), tungsten (W), molybdenum (Mo), silicon phosphide (SiP), titanium silicon (TiSi), titanium nitride (TiN), titanium aluminide (TiAl), silicon germanium (SiGe), silicon germanium boron (SiGeB), hafnium oxide (HfO₂), aluminum oxide (Al₂O₃) or combinations thereof. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with an open bottom.

As used herein, the term “processing chamber” includes portions of a processing chamber adjacent to the substrate surface without encompassing the complete interior volume of the processing chamber. For example, in a sector of a spatially separated processing chamber, the portion of the processing chamber adjacent the substrate surface is purged of one or more reactive compounds by any suitable technique including, but not limited to, moving the substrate through a gas curtain to a portion or sector of the processing chamber that contains none or substantially none of the reactive compounds.

As used herein, the term “atomic layer deposition” or “cyclical deposition” refers to the sequential exposure of two or more reactive compounds to deposit a layer of material on a substrate surface. The substrate, or portion of the substrate surface is exposed sequentially to the two or more reactive compounds which are introduced into a reaction zone of a processing chamber. The sequential exposure of the reactive gases prevents or minimizes gas phase reactions between the reactive gases. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In one or more embodiments, the time-domain ALD process can be performed with more than two reactive compounds in a predetermined sequence.

In an aspect of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. In one or more embodiments, the spatial ALD process can be performed with more than two reactive compounds in a predetermined sequence.

In some embodiments, the substrate surface is exposed to the first reactive compound and the second reactive compound substantially sequentially. As used herein throughout the specification, “substantially sequentially” means that most of the duration of the first reactive compound exposure does not overlap with the second reactive compound exposure, although there may be some overlap.

As used herein, the term “chemical vapor deposition” refers to the exposure of at least one reactive compound to deposit a layer of material on the substrate surface. In some embodiments, the chemical vapor deposition (CVD) process comprises mixing the two or more reactive compounds in the processing chamber to allow gas phase reactions of the reactive compounds and deposition. In some embodiments, the CVD process comprises exposing the substrate surface to two or more reactive compounds simultaneously. In some embodiments, the CVD process comprises exposing the substrate surface to a first reactive compound continuously with an intermittent exposure to a second reactive compound. In some embodiments, the substrate surface undergoes the CVD reaction to deposit a film having a predetermined thickness. In the CVD process, the film can be deposited in one exposure to the mixed reactive compounds or can be multiple exposures to the mixed reactive compounds with purges between. In some embodiments, the substrate surface is exposed to the first reactive compound and the second reactive compound substantially simultaneously.

As used herein throughout the specification, “substantially simultaneously” means that most of the duration of the first reactive compound exposure overlaps with the second reactive compound exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive compound is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive compound.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is and should not be construed or interpreted as limiting the scope of the embodiments described herein.

As used herein, the terms “liner” or “barrier layer” refer to a layer conformally formed along at least a portion of the sidewalls and/or lower surface of an opening such that a substantial portion of the opening prior to the deposition of the layer remains unfilled after deposition of the layer. The liner may be formed along the entirety of the sidewalls and lower surface of the opening. The liner can be formed by any process known to a person skilled in the art. In some embodiments, the liner comprises a metal nitride, a PVD metal or combinations thereof. In one or more embodiments, the “liner” or “barrier layer” can also be formed selectively at the bottom of the structure.

Transistors are circuit components or elements that are often formed on semiconductor devices. Many transistors may be formed on a semiconductor device in addition to capacitors, inductors, resistors, diodes, conductive lines, or other elements, depending upon the circuit design. The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals.

Generally, a transistor includes a gate formed between source and drain regions. The source and drain regions may include a doped region of a substrate and may exhibit a doping profile suitable for a particular application. The gate is positioned over the channel region and may include a gate dielectric interposed between a gate electrode and the channel region in the substrate.

As used herein, the term “field effect transistor” or “FET” refers to a transistor that uses an electric field to control the electrical behavior of the device. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

Embodiments of the disclosure provide semiconductor structures and methods for forming a semiconductor structure. In order to improve speed and drive current in devices having advanced nodes below the 2 nm node, reductions in contact resistance are needed. In one or more embodiments, integration of molybdenum with titanium shows a large contact resistance (R_{c}) reduction benefit. Surprisingly, the reduction is observed in NMOS contacts, even though molybdenum (Mo) is considered a p-type metal and, if only molybdenum is used in NMOS contacts, the contact resistance is very high. Accordingly, the performance on NMOS in one or more embodiments, is especially unexpected.

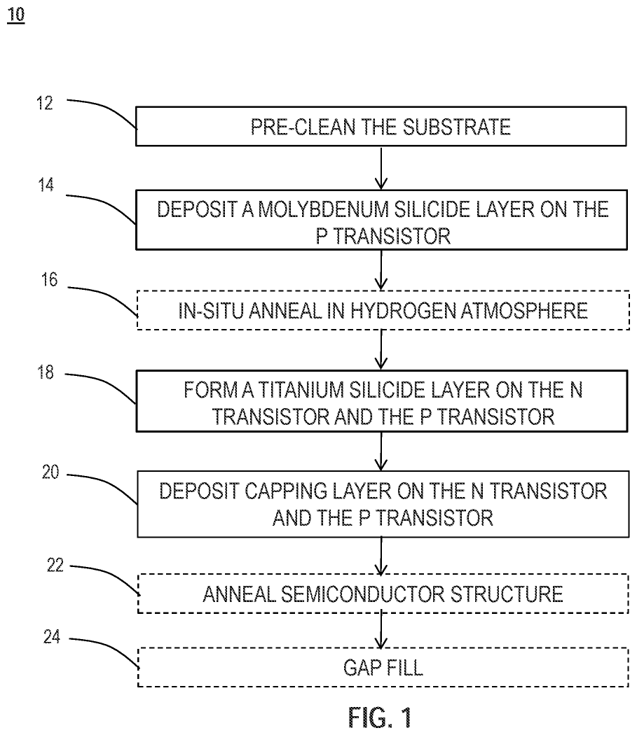

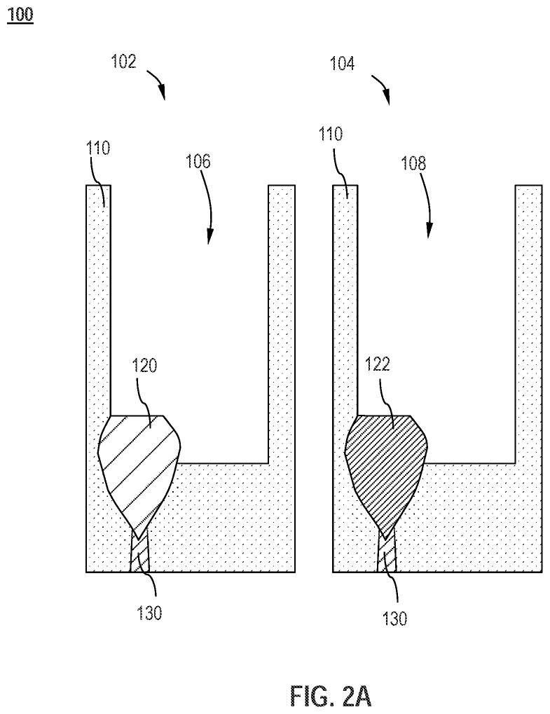

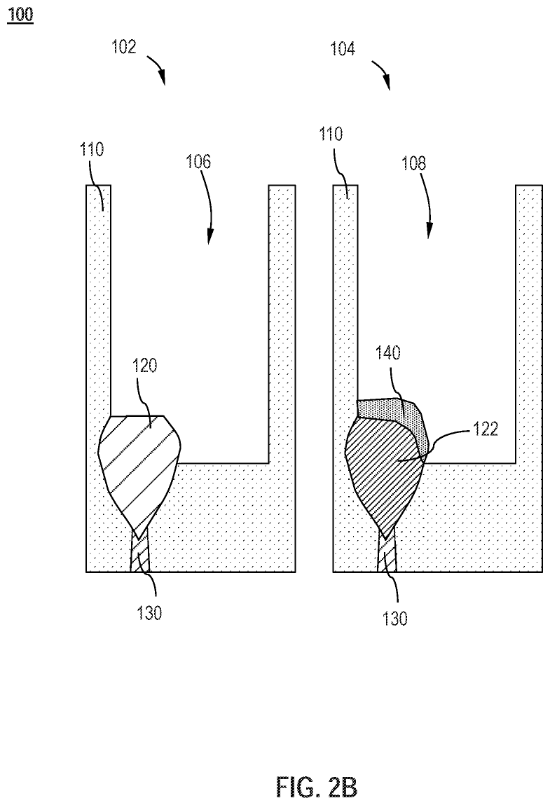

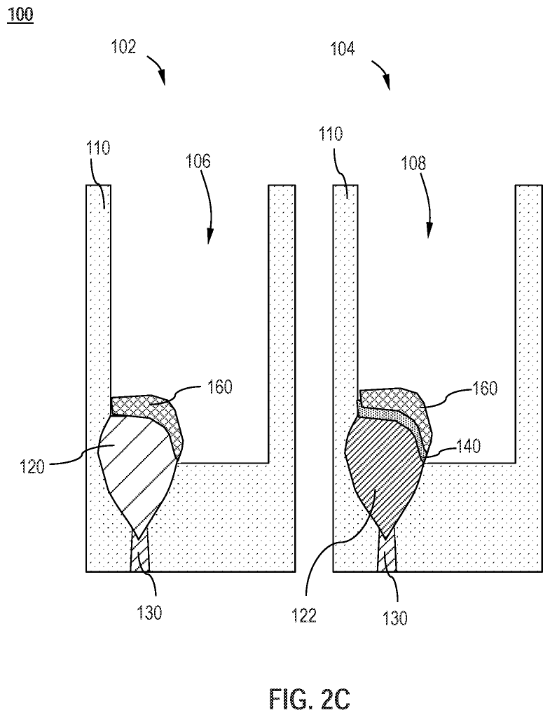

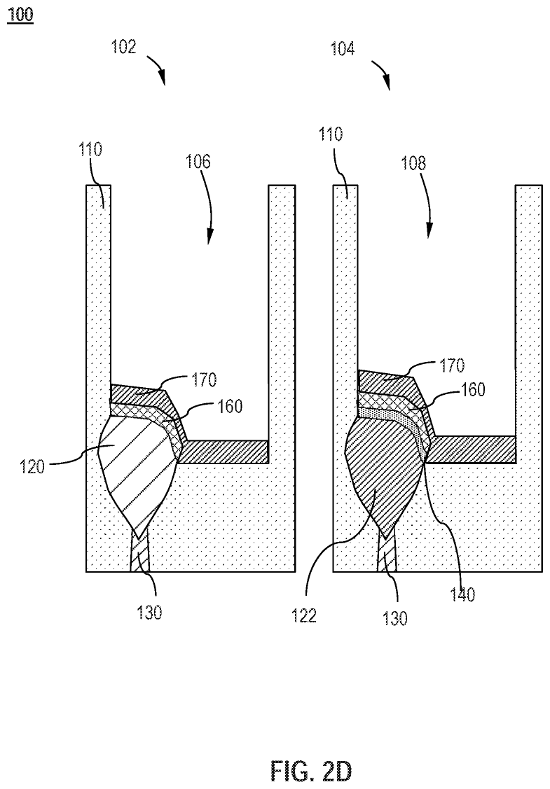

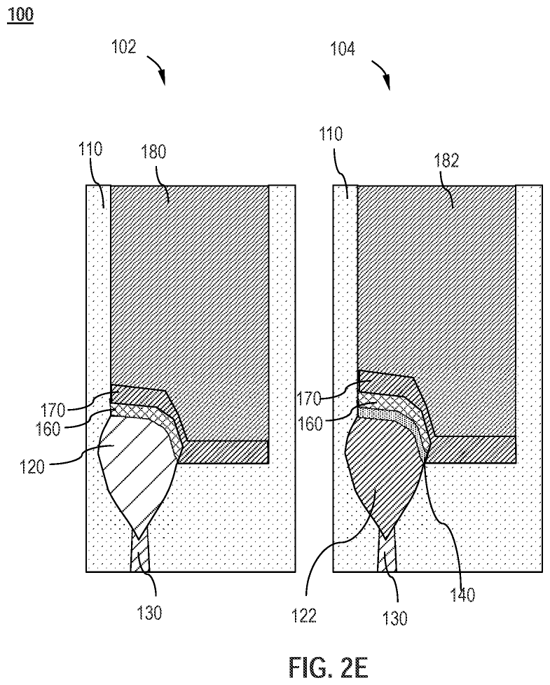

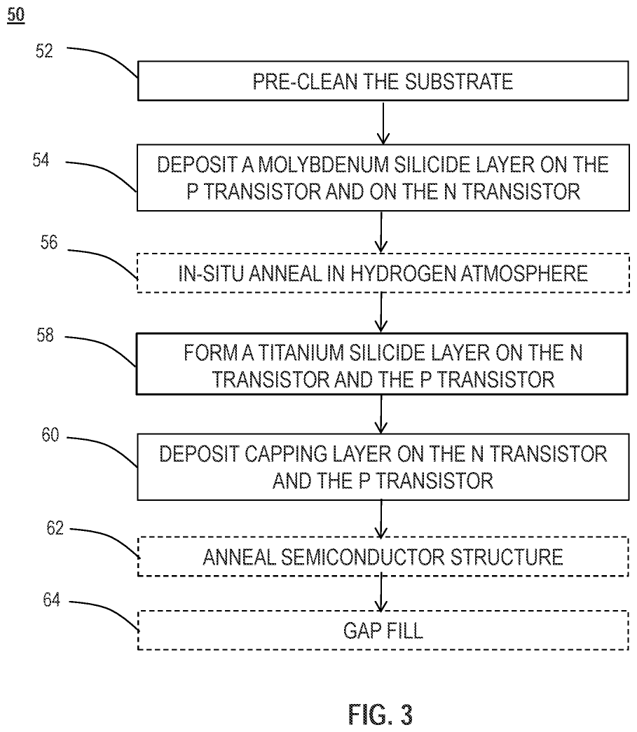

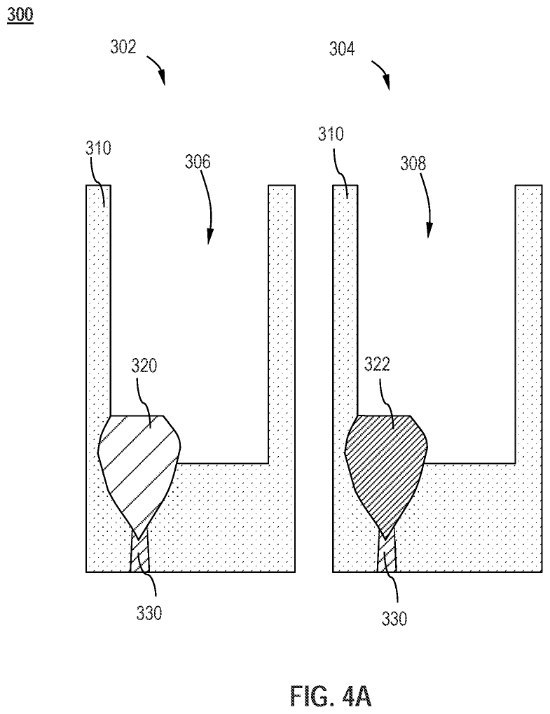

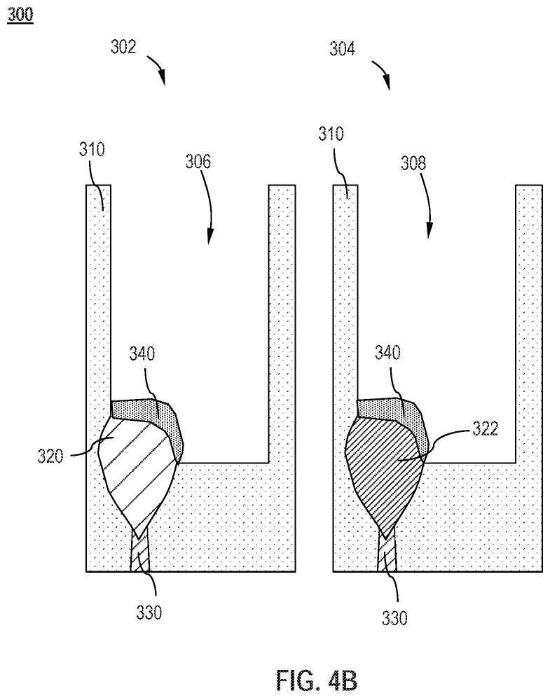

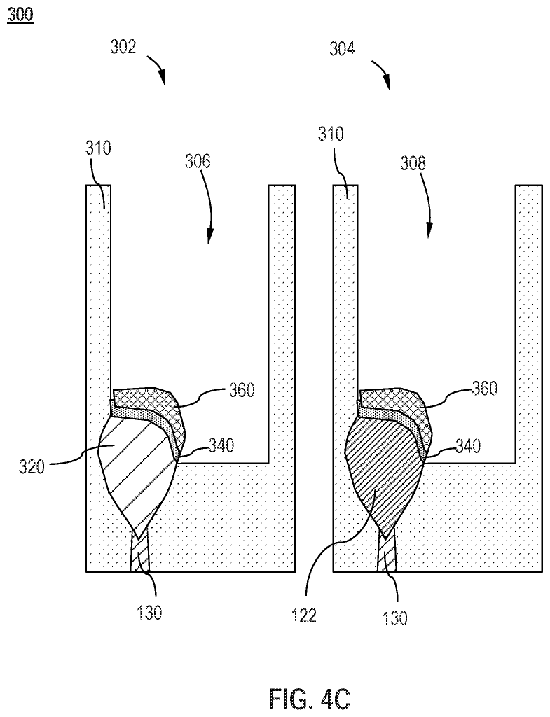

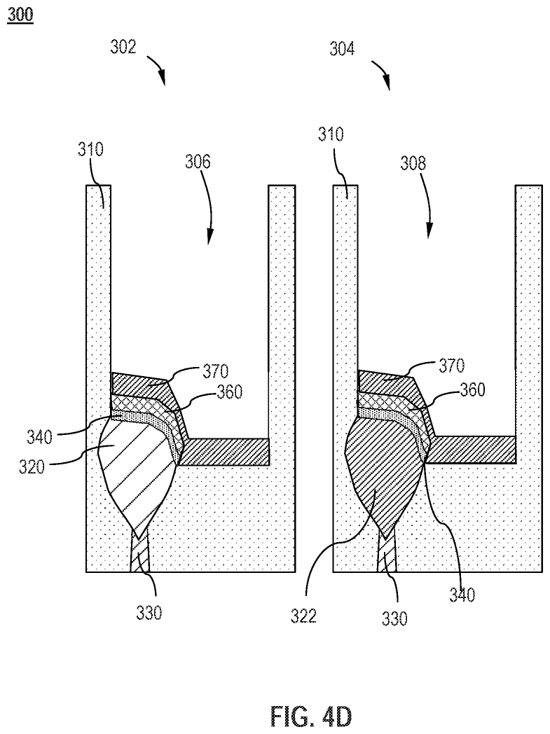

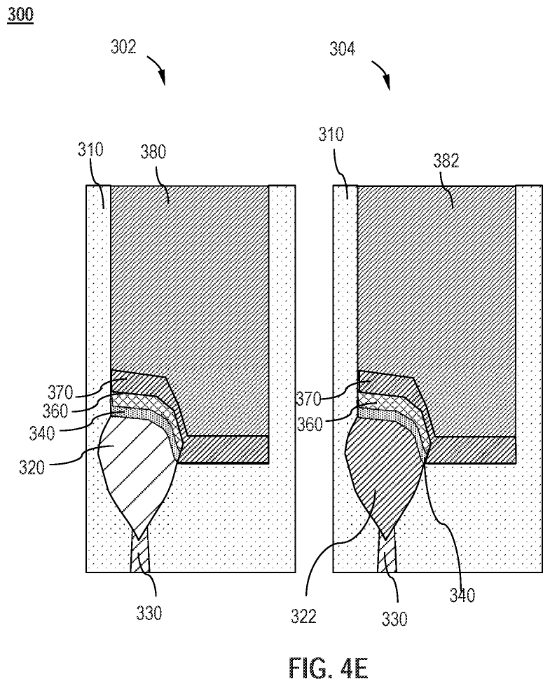

The embodiments of the disclosure are described by way of the Figures, which illustrate processes for forming NMOS and PMOS. FIG. 1 illustrates a process flow diagram of a method 10 of forming a semiconductor structure. FIG. 1 illustrates a method of forming any of the semiconductor structures of one or more embodiments shown in FIGS. 2A-2E. FIG. 3 illustrates a process flow diagram of a method 50 of forming a semiconductor structure. FIG. 3 illustrates a method of forming any of the semiconductor structures of one or more embodiments shown in FIGS. 4A-4E.

Referring to FIG. 1, in one or more embodiments, the method 10 of forming a semiconductor structure comprises, at operation 12, the substrate is pre-cleaned. Pre-cleaning the substrate may be done by any suitable method known to the skilled artisan. At operation 14, a molybdenum silicide (MoSi) layer is deposited on the p transistor. At operation 16, the method 10 optionally includes in-situ annealing the transistor in an atmosphere of hydrogen (H₂). At operation 18, the method 10 comprises forming a titanium silicide (TiSi) layer on the n transistor and on the p transistor. At operation 20, the method 10 comprises forming a capping layer on the n transistor and on the p transistor. At operation 22, the method 10 optionally comprises annealing the semiconductor structure. At operation 24, the method 10 optionally comprises gap filling.

In one or more unillustrated embodiments, a substrate may be patterned to form at least one of the first opening 106 and a second opening 108. In one or more embodiments, patterning the substrate comprises using one or more patterning techniques known to one of ordinary skill in the art of microelectronic device manufacturing. In some embodiments, the semiconductor structure 100 is provided and no patterning to form the semiconductor structure 100 is required.

With reference to FIGS. 1 and 2A-2E, at operation 12, the method 10 comprises pre-cleaning the substrate. In one or more embodiments, keeping the pre-cleaning process under vacuum ensures that no oxide is introduced/formed on the substrate surface during the method. In some embodiments, pre-cleaning the substrate (or surface of the substrate) removes oxides from the surface. In some embodiments, the oxides are native oxides. In some embodiments, cleaning the surface forms a surface that is substantially free of oxides. As used in this manner, the term “substantially free of oxides” means that there are less than or equal to 5%, 2%, 1% or 0.5% of oxygen atoms on the surface. In one or more embodiments, anisotropic etching is used to remove oxide from the surface. In one or more embodiments, anisotropic etching removes oxide more from the surface of the source/drain material than the dielectric material. In one or more embodiments, pre-cleaning the surface forms a source/drain material that is substantially free of oxide.

With reference to FIGS. 2A-2E, a semiconductor structure 100 is shown. The semiconductor structure 100 comprises an n transistor 102 and a p transistor 104. In one or more embodiments, each of the n transistor 102 and the p transistor 104 comprise a dielectric material 110, a source/drain material 120, 122, and a substrate 130.

In one or more embodiments, the dielectric material 110 may comprise any suitable dielectric material known to the skilled artisan. As used herein, the term “dielectric material” refers to an electrical insulator that can be polarized in an electric field. In some embodiments, the dielectric material 110 comprises one or more of silicon, silicon oxide, silicon nitride, silicon carbide, and low-κ dielectrics. As used herein, terms such as “silicon oxide” and “silicon nitride” refer to materials comprising silicon and oxygen or silicon and nitrogen. “Silicon oxide” and “silicon nitride” should not be understood to imply any stoichiometric ratio. Stated differently, a dielectric material comprising silicon oxide or silicon nitride may be stoichiometric or non-stoichiometric, silicon-rich, or silicon-poor. In some embodiments, the dielectric material 110 comprises silicon oxide (SiO₂). In some embodiments, the dielectric material 110 comprises silicon nitride (SiN).

In some embodiments, the n transistor 102 and the p transistor 104 comprise source and drain contacts. In one or more embodiments, the source/drain material 120, 122 may have more than one layer.

In one or more specific embodiments, the source/drain material 120 of the n transistor 102 comprises silicon (Si). The source/drain 120 material of the n transistor 102 may be doped or undoped. In one or more embodiments, the source/drain material 120 of the n transistor 102 comprises silicon (Si) doped with phosphorous (P).

In one or more embodiments, the source/drain material 122 of the p transistor 104 comprises silicon germanium (SiGe). In one or more embodiments, the silicon germanium (Ge) may have any suitable concentration of germanium. In some embodiments, the silicon germanium (SiGe) has a concentration of germanium in a range of from 10% to 100%, or in a range of from 20% to 60%. The source/drain 122 material of the p transistor 104 may be doped or undoped. In one or more embodiments, the source/drain material 122 of the p transistor 104 comprises silicon germanium (SiGe) doped with boron (B).

Referring to FIGS. 2A-2E, in one or more embodiments, there is a first opening 106 over the n transistor 102, and there is a second opening 108 over the p transistor 104. The first opening 106 and the second opening 108 can have any suitable aspect ratio (ratio of the depth of the opening to the width of the opening). In one or more embodiments, the first opening 106 and the second opening 108 may independently have an aspect ratio in a range of from 3:1 to 15:1, or in a range of from 6:1 to 15:1, or in a range of from 9:1 to 15:1, or in a range a range of from 12:1 to 15:1. In one or more embodiments, the first opening 106 and the second opening 108 may independently have an aspect ratio greater than 10:1.

With reference to FIG. 1 and FIG. 2B, at operation 14, a molybdenum silicide (MoSi) layer 140 is deposited on one or more of the p transistor 104 source/drain 122 and the n transistor 102 source/drain 122. In the embodiment illustrated in FIGS. 2A-2E, the molybdenum silicide (MoSi) layer 140 is deposited on only the p transistor 104 source/drain 122, but one of skill in the art will recognize that the deposition of the molybdenum silicide layer 104 does not need to be selective to the p transistor. In one or more embodiments, the molybdenum silicide layer 140 may be formed by any suitable means. In one or more embodiments, the molybdenum silicide layer 140 is deposited on the p transistor by a chemical vapor deposition (CVD) process.

In some embodiments, the molybdenum silicide layer 140 is selectively deposited on the source/drain material 122 of the p-transistor and not on the source/drain material 120 of the n-transistor. As used in this specification and the appended claims, the term “selectively depositing a film on one surface over another surface”, and the like, means that a first amount of the film is deposited on the first surface and a second amount of film is deposited on the second surface, where the second amount of film is less than the first amount of film, or no film is deposited on the second surface.

The selectivity of a deposition process is generally expressed as a multiple of growth rate. For example, if one surface is grown (or deposited on) twenty-five times faster than a different surface, the process would be described as having a selectivity of 25:1. In this regard, higher ratios indicate more selective processes.

In one or more embodiments, the substrate 100 is optionally exposed to a blocking compound. This process step may be useful for controlling the selectivity of the deposition process on a substrate comprising both a metal surface and a dielectric surface.

In one or more embodiments, the molybdenum silicide (MoSi) layer 140 is deposited by CVD. The substrate 100 is exposed to a process gas for a period of time. The process gas comprises a molybdenum precursor which reacts with the substrate surface to deposit a molybdenum film. The reactive gas may also be referred to as the metal precursor gas.

The molybdenum precursor may be any suitable precursor to react with the substrate. In some embodiments, the molybdenum precursor comprises a metal center and one or more ligands. In some embodiments, the metal center comprises one or more metal atoms. Stated differently, in some embodiments, the metal precursor is one or more of a dimer, trimer, or tetramer.

The molybdenum precursor can be any suitable precursor with a decomposition temperature above the deposition temperature. The molybdenum precursors of one or more embodiments are volatile and thermally stable, and, thus, suitable for vapor deposition.

In some embodiments, the molybdenum precursor comprises a molybdenum halide. As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—). Accordingly, as used herein, the term “molybdenum halide” refers to any coordination complex of molybdenum with one or more halogen or halide ligand. The term molybdenum halide includes molybdenum mixed halides which have at least two different halide atoms.

In one or more embodiments, the molybdenum halide is selected from one or more of molybdenum chloride, molybdenum pentachloride, molybdenum bromide, molybdenum iodide, molybdenum bromochloride, molybdenum bromoiodide, molybdenum chlorobromide, molybdenum chloroiodide, molybdenum iodobromide, molybdenum iodochloride.

In other embodiments, the molybdenum precursor comprises substantially no oxygen or nitrogen atoms. Accordingly, in these embodiments, the metal precursor comprises no carbonyl, oxo, amine, or imine ligands. Within these parameters, the number of ligands and types of ligands on the molybdenum precursor can vary, based on, for example, the oxidation state of the molybdenum atom. The molybdenum precursor can be homoleptic or heteroleptic. In some embodiments, the molybdenum precursor comprises at least one ligand comprising an optionally alkyl substituted cyclopentadiene (Cp) ring. In some embodiments, the molybdenum precursor comprises at least one ligand comprising an optionally alkyl substituted benzene ring. In some embodiments, the molybdenum precursor comprises at least one p-cymene ligand. In some embodiments, the molybdenum precursor comprises at least one ligand comprising an open or closed diene.

In one or more embodiments, the molybdenum precursor is delivered to the processing chamber as a molybdenum precursor gas or via a carrier gas such as argon (Ar), nitrogen (N₂), hydrogen (H₂), or the like. The molybdenum precursor gas or carrier gas may be provided in one or more pulses or continuously. The flow rate of the molybdenum precursor gas or carrier gas can be any suitable flow rate including, but not limited to, flow rates in the range of about 1 to about 5000 sccm, or in the range of about 2 to about 4000 sccm, or in the range of about 3 to about 3000 sccm or in the range of about 5 to about 2000 sccm.

The molybdenum precursor gas can be provided at any suitable pressure including, but not limited to, a pressure in the range of about 5 mTorr to about 500 Torr, or in a range of about 10 mTorr to about 500 Torr, or in the range of about 100 mTorr to about 500 Torr, or in the range of about 5 Torr to about 500.

The period of time that the substrate is exposed to the molybdenum precursor gas may be any suitable amount of time necessary to allow the metal precursor to react with the substrate surface. For example, the process gas may be flowed into the process chamber for a period of greater than or equal to about 60 seconds. In some embodiments, the period of exposure to the molybdenum precursor is about 0.5 seconds. In some embodiments, the period of exposure to the molybdenum precursor is about 100 seconds, about 200 seconds, about 300 seconds, about 400 seconds or about 500 seconds.

In one or more embodiments, the deposition process is cyclic; per cycle, the exposure time per cycle of the molybdenum precursor is about 500 msec. Then the flow is turned off for about 3.5 sec. In one or more embodiments, the deposition process is cyclic, and each cycle can be represented as follows: H₂ gas is on all the time; precursor exposure is 0.5 sec, together with H₂; purge, with H₂ only is on for 3.5 sec; total cycle duration is 4 sec; cycles are repeated until the target molybdenum thickness is achieved.

The temperature of the substrate during exposure to the molybdenum precursor can be controlled, for example, by setting the temperature of the substrate support or susceptor. This temperature is also referred to as the deposition temperature. In some embodiments the substrate is held at a temperature in the range of about 0° C. to about 600° C., or in the range of about 25° C. to about 500° C., or in the range of about 50° C. to about 450° C., or in the range of about 100° C. to about 400° C., or in the range of about 200° C. to about 400° C., or in the range of about 250° C. to about 350° C. In some embodiments, the substrate is maintained at a temperature below the decomposition temperature of the metal precursor.

In one or more embodiments, the substrate is maintained at a temperature less than or equal to about 350° C., or less than or equal to about 310° C., or less than or equal to about 300° C., or less than or equal to about 250° C., or less than or equal to about 200° C. In one or more embodiments, the substrate is maintained at a temperature greater than or equal to about 200° C., or greater than or equal to about 300° C., or greater than about 350° C. In some embodiments, the substrate is maintained at a temperature in a range of from about 200° C. to about 310° C.

In some embodiments, a carrier gas may additionally be provided to the process chamber at the same time as the molybdenum precursor gas. The carrier gas may be mixed with the molybdenum precursor gas (e.g., as a diluent gas) or be provided separately and can be pulsed or of a constant flow. In some embodiments, the carrier gas is flowed into the processing chamber at a constant flow in the range of about 1 to about 10000 sccm. The carrier gas may be any carrier gas, for example, such as argon, helium, neon, hydrogen, nitrogen, or combinations thereof.

The deposition process is performed as a thermal process without the use of plasma reactants. Stated differently, the method is performed without plasma.

In one or more embodiments, it is determined whether the molybdenum film has achieved a predetermined thickness. If the predetermined thickness has not been achieved, the method returns to continue exposing the substrate to the molybdenum precursor until the predetermined thickness is reached. In some embodiments, the molybdenum film may be deposited to form a total layer thickness of about 10 Å to about 10,000 Å, or in some embodiments, about 20 Å to about 1000 Å, or in some embodiments, about 50 Å to about 200 Å.

In one or more embodiments, the molybdenum halide precursor reacts directly with the silicon or silicon germanium of the source/drain material 120, 122 to form the molybdenum silicide layer 140.

In other embodiments, once the molybdenum film has reached its predetermined thickness, the molybdenum film may be exposed to a reactant to form the molybdenum silicide layer 140. In one or more embodiments, the reactant comprises an oxidizing agent, a reducing agent, or combinations thereof. In some embodiments, the reactant comprises hydrogen (H₂), ammonia (NH₃), silane, polysilane, or combinations thereof. In some embodiments, the silane is selected from one or more of disilane, trisilane, tetrasilane, higher order silanes, and substituted silane. In specific embodiments, the reactant comprises a silane to form the molybdenum silicide (MoSi) layer 140. In one or more embodiments, the reactant is flowed over the surface using a carrier gas. In some embodiments, the carrier gas is an inert gas. In some embodiments, the inert gas comprises one or more of N₂, Ar, and He. In other embodiments, the reactant gas may be flowed continuously and the molybdenum precursor flow to the chamber is turned on and off.

In other embodiments, at operation 16, optionally, the molybdenum silicide layer 140 may be annealed. The annealing may occur at any suitable temperature in any suitable atmosphere. In some embodiments, the molybdenum silicide layer 140 is annealed in an atmosphere of hydrogen (H₂) gas at a temperature in a range of from 200° C. to 600° C., or in a range of from 400° C. to 500° C. In one or more embodiments, the molybdenum silicide layer 140 is annealed at a pressure in a range of from 10 mTorr to 20 Torr, or in a range of from 100 mTorr to 20 Torr, or in a range of from 500 mTorr to 10 Torr.

In one or more embodiments, the molybdenum silicide layer 140 may have any suitable thickness. In some embodiments, the molybdenum silicide layer 140 has a thickness in a range of from 20 Å to about 100 Å, or in a range of from about 30 Å to about 90 Å, or in a range of from about 40 Å to about 80 Å, or in a range of from about 50 Å to about 70 Å. In one or more embodiments, the molybdenum silicide (MoSi) layer 140 has a thickness of about 40 Å. The molybdenum silicide (MoSi) layer 140 on the p transistor 102 has a Schottky barrier height in a range of from about 0.65 eV to about 0.95 eV.

Referring to FIG. 1 and FIG. 2C, at operation 18, a titanium silicide (TiSi) layer 160 is deposited on the source/drain 120 of the n transistor 102 and on the source/drain 122 of the p transistor. In one or more embodiments, the titanium silicide (TiSi) layer 160 may have any suitable thickness. In some embodiments, the titanium silicide (TiSi) layer 160 has a thickness in a range of from 20 Å to about 100 Å, or in a range of from about 30 Å to about 90 Å, or in a range of from about 40 Å to about 80 Å, or in a range of from about 50 Å to about 70 Å. In one or more embodiments, the titanium silicide (TiSi) layer 160 has a thickness of about 40 Å.

The titanium silicide (TiSi) layer 160 may be formed according to any suitable process known to the skilled artisan. In one or more embodiments, the structure 100 is first cleaned to remove oxides from the surface. In some embodiments, the oxides are native oxide. In some embodiments, cleaning the surface forms a surface that is substantially free of oxide. As used in this manner, the term “substantially free of oxide” means that there are less than or equal to 5%, 2%, 1% or 0.5% of oxygen atoms on the surface. In one or more embodiments, anisotropic etching is used to remove oxide from the surface.

In one or more embodiments, to form the titanium silicide (TiSi) layer 160, a metal film is selectively formed on the source/drain 120 of the n transistor 102 and on the source/drain 122 of the p transistor, e.g., on the molybdenum silicide layer 140. In some embodiments, the structure 100 is exposed to a metal precursor and a reactant. The metal film can be deposited by an ALD deposition process, a CVD deposition process, a plasma enhanced CVD process, or combinations thereof. In some embodiments, the metal film comprises a titanium silicide (TiSi) film.

In one or more embodiments, the metal precursor comprises a titanium precursor. In some embodiments, the titanium precursor comprises a titanium halide. In some embodiments, the titanium halide comprises titanium fluoride, titanium chloride, or combinations thereof. In specific embodiments, the titanium precursor comprises titanium fluoride. In other specific embodiments, the titanium precursor comprises titanium chloride. In one or more embodiments, the precursor is flowed over the surface using a carrier gas. In some embodiments, the carrier gas is flowed through an ampoule comprising the precursor. In some embodiments, the carrier gas is an inert gas. In some embodiments, the inert gas comprises one or more of N₂, Ar, and He.

In one or more embodiments, the reactant comprises an oxidizing agent, a reducing agent, or combinations thereof. In some embodiments, the reactant comprises hydrogen (H₂), silane, polysilane, or combinations thereof. In some embodiments, the silane is selected from one or more of disilane, trisilane, tetrasilane, higher order silanes, and substituted silane. In specific embodiments, the reactant comprises a silane to form the titanium silicide (TiSi) layer 160. In one or more embodiments, the reactant is flowed over the surface using a carrier gas. In some embodiments, the carrier gas is an inert gas. In some embodiments, the inert gas comprises one or more of Ar and He. In other embodiments, the reactant gas may be flowed continuously and the titanium precursor flow to the chamber is turned on and off.

In other embodiments the titanium silicide film is formed by reacting titanium tetrachloride (TiCl₄), hydrogen (H₂), and plasma with the underlying silicon substrate. In one or more embodiments, an additional silicon source is not provided.

In one or more embodiments, by combining Mo with Ti in integrated fashion, the contact resistance is reduced more than if there were individual metal silicides. In other words, the combination of Mo and titanium Ti leads to contact resistance, which is lower than with Mo only, and lower than with Ti only.

Referring to FIG. 1, in one or more embodiments, operations 12 and 14 are conducted in an integrated system without vacuum break between operations. In other embodiments, operations 12, 14, 16, and 18 are conducted in an integrated system without vacuum break between operations.

Referring to FIG. 1 and FIG. 2D, at operation 20, a capping layer 170 may be formed on each of the n transistor 102 and the p transistor 104. The capping layer 170 may comprise any suitable material known to the skilled artisan. In one or more embodiments, the capping layer 170 comprises a PVD metal film. In one or more embodiments, the capping layer 170 is selected from one or more of titanium nitride (TiN), tantalum nitride (TaN), tungsten nitride (WN), molybdenum nitride (MoN), PVD tungsten (W), PVD molybdenum (Mo), and PVD ruthenium (Ru). In one or more embodiments, the capping layer 170 prevents formation of oxides on the titanium silicide (TiSi) layer 160.

In additional embodiments, the capping layer 170 is selectively formed on a top surface of titanium silicide (TiSi) layer 160 through the nitridation of the titanium silicide (TiSi) layer 160 by one or more of ammonia (NH₃) plasma, N₂/H₂ plasma, or the like.

Referring to FIG. 1, in some embodiments, at operation 22, optionally annealing the semiconductor structure 100 may further reduce the contact resistance of the structure 100. In one or more embodiments, annealing the semiconductor structure 100 may produce a smooth surface.

The semiconductor structure 100 can be annealed by any process known to a person skilled in the art. In some embodiments, the semiconductor structure is annealed by a rapid thermal process (RTP). In one or more embodiments, the rapid thermal process (RTP) comprises annealing the semiconductor structure 100 to a temperature in a range of about 400° C. to about 700° C. In one or more embodiments, the rapid thermal process (RTP) comprises annealing the semiconductor structure 100 to a temperature of about 600° C.

With reference to FIG. 1 and FIG. 2E, at operation 24, the first opening 106 over the n transistor 102 and the second opening 108 over the p transistor 104 are independently filled with a gap fill material 180 and a gap fill material 182, respectively. In one or more embodiments, the gap fill material 180 and the gap fill material 182 are substantially free of voids or seams. The gap fill material 180 and the gap fill material 182 may independently comprise any suitable gap fill materials known to the skilled artisan. In one or more embodiments, the gap fill material 180 and the gap fill material 182 independently comprise one or more of tungsten (W), molybdenum (Mo), cobalt (Co), and ruthenium (Ru). In one or more embodiments, the gap fill material 180 in the first opening 106 over the n transistor 102 is the same as the gap fill material 182 in the second opening 108 over the p transistor 104. In one or more embodiments, the gap fill material 180 in the first opening 106 over the n transistor 102 is different than the gap fill material 182 in the second opening 108 over the p transistor 104. In one or more embodiments, the gap fill material 180 and the gap fill material 182 are the same and comprise tungsten (W).

The gap filling process may comprise any suitable gap filling process known to the skilled artisan. In one or more embodiments, the gap filling process comprises exposing the semiconductor structure 100 to a metal precursor and a reactant. In some embodiments, the metal precursor comprises one or more of a molybdenum precursor, a tungsten precursor, a cobalt precursor, and a ruthenium precursor.

In some embodiments, the gap filling process is a bottom-up gap filling process. In other embodiments, the gap filling process comprises a conformal gap filling process.

Referring to FIG. 3, in one or more embodiments, the method 50 of forming a semiconductor structure comprises, at operation 52, pre-cleaning the substrate. Pre-cleaning the substrate may be done by any suitable method known to the skilled artisan. At operation 54, a molybdenum silicide (MoSi) layer is deposited on both the p transistor and on the n transistor. At operation 56, the method 50 optionally includes in-situ annealing the transistors in an atmosphere of hydrogen (H₂). At operation 58, the method 50 comprises forming a titanium silicide (TiSi) layer on the n transistor and on the p transistor. At operation 60, the method 50 comprises forming a capping layer on the n transistor and on the p transistor. At operation 62, the method 50 optionally comprises annealing the semiconductor structure. At operation 64, the method 50 optionally comprises gap filling.

With reference to FIGS. 3 and 4A-4E, at operation 52, the method 50 comprises pre-cleaning the substrate. In one or more embodiments, keeping the pre-cleaning process under vacuum ensures that no oxide is introduced/formed on the substrate surface during the method. In some embodiments, pre-cleaning the substrate (or surface of the substrate) removes oxides from the surface. In some embodiments, the oxides are native oxides. In some embodiments, cleaning the surface forms a surface that is substantially free of oxides. As used in this manner, the term “substantially free of oxides” means that there are less than or equal to 5%, 2%, 1% or 0.5% of oxygen atoms on the surface. In one or more embodiments, anisotropic etching is used to remove oxide from the surface. In one or more embodiments, anisotropic etching removes oxide more from the surface of the source/drain material than the dielectric material. In one or more embodiments, pre-cleaning the surface forms a source/drain material that is substantially free of oxide.

With reference to FIGS. 4A-4E, a semiconductor structure 300 is shown. The semiconductor structure 300 comprises an n transistor 302 and a p transistor 304. In one or more embodiments, each of the n transistor 302 and the p transistor 304 comprise a dielectric material 310, a source/drain material 320, 322, and a substrate 330.

In one or more embodiments, the dielectric material 310 may comprise any suitable dielectric material known to the skilled artisan and as described herein above with respect to dielectric material 110. In some embodiments, the dielectric material 310 comprises silicon oxide (SiO₂). In some embodiments, the dielectric material 310 comprises silicon nitride (SiN).

In some embodiments, the n transistor 302 and the p transistor 304 comprise source and drain contacts. In one or more embodiments, the source/drain material 320, 322 may have more than one layer.

In one or more specific embodiments, the source/drain material 320 of the n transistor 302 comprises silicon (Si). The source/drain 320 material of the n transistor 302 may be doped or undoped. In one or more embodiments, the source/drain material 320 of the n transistor 302 comprises silicon (Si) doped with phosphorous (P).

In one or more embodiments, the source/drain material 322 of the p transistor 304 comprises silicon germanium (SiGe). In one or more embodiments, the silicon germanium (Ge) may have any suitable concentration of germanium. In some embodiments, the silicon germanium (SiGe) has a concentration of germanium in a range of from 10% to 100%, or in a range of from 20% to 60%. The source/drain 322 material of the p transistor 304 may be doped or undoped. In one or more embodiments, the source/drain material 322 of the p transistor 304 comprises silicon germanium (SiGe) doped with boron (B).

Referring to FIGS. 4A-4E, in one or more embodiments, there is a first opening 306 over the n transistor 302, and there is a second opening 308 over the p transistor 304. The first opening 306 and the second opening 308 can have any suitable aspect ratio (ratio of the depth of the opening to the width of the opening). In one or more embodiments, the first opening 306 and the second opening 308 may independently have an aspect ratio in a range of from 3:1 to 15:1, or in a range of from 6:1 to 15:1, or in a range of from 9:1 to 15:1, or in a range a range of from 12:1 to 15:1. In one or more embodiments, the first opening 306 and the second opening 308 may independently have an aspect ratio greater than 10:1.

With reference to FIG. 3 and FIG. 4B, at operation 54, a molybdenum silicide (MoSi) layer 340 is deposited on both the p transistor 304 source/drain 322 and on the n transistor source/drain 320. In one or more embodiments, the molybdenum silicide layer 340 may be formed by any suitable means, as described above with respect to the molybdenum silicide (MoSi) layer 140. In one or more embodiments, a molybdenum silicide layer 340 is deposited on the p transistor and on the n transistor by a chemical vapor deposition (CVD) process, as described above with respect to the molybdenum silicide layer 140.

In one or more embodiments, it is determined whether the molybdenum film has achieved a predetermined thickness. If the predetermined thickness has not been achieved, the method returns to continue exposing the substrate to the molybdenum precursor until the predetermined thickness is reached. In some embodiments, the molybdenum film may be deposited to form a total layer thickness of about 10 Å to about 10,000 Å, or in some embodiments, about 20 Å to about 1000 Å, or in some embodiments, about 50 Å to about 200 Å.

In one or more embodiments, once the molybdenum film has reached its predetermined thickness, the molybdenum film may be exposed to a reactant to form the molybdenum silicide layer 340, as described above with respect to the molybdenum silicide layer 140.

In other embodiments, at operation 56, optionally, the molybdenum silicide layer 340 may be annealed. The annealing may occur at any suitable temperature in any suitable atmosphere. In some embodiments, the molybdenum silicide layer 340 is annealed in an atmosphere of hydrogen (H₂) gas at a temperature in a range of from 200° C. to 600° C., or in a range of from 400° C. to 500° C. In one or more embodiments, the molybdenum silicide layer 340 is annealed at a pressure in a range of from 10 mTorr to 20 Torr, or in a range of from 100 mTorr to 20 Torr, or in a range of from 500 mTorr to 10 Torr.

In one or more embodiments, the molybdenum silicide layer 340 may have any suitable thickness. In some embodiments, the molybdenum silicide layer 340 has a thickness in a range of from 20 Å to about 100 Å, or in a range of from about 30 Å to about 90 Å, or in a range of from about 40 Å to about 80 Å, or in a range of from about 50 Å to about 70 Å. In one or more embodiments, the molybdenum silicide (MoSi) layer 340 has a thickness of about 40 Å.

Referring to FIG. 3 and FIG. 4C, at operation 58, a titanium silicide (TiSi) layer 360 is deposited on the source/drain 320 of the n transistor 302 and on the source/drain 322 of the p transistor. In one or more embodiments, the titanium silicide (TiSi) layer 360 may have any suitable thickness. In some embodiments, the titanium silicide (TiSi) layer 360 has a thickness in a range of from 20 Å to about 100 Å, or in a range of from about 30 Å to about 90 Å, or in a range of from about 40 Å to about 80 Å, or in a range of from about 50 Å to about 70 Å. In one or more embodiments, the titanium silicide (TiSi) layer 360 has a thickness of about 40 Å.

The titanium silicide (TiSi) layer 360 may be formed according to any suitable process known to the skilled artisan, as described herein above with respect to the titanium silicide (TiSi) layer 160. In one or more embodiments, the structure 100 is first cleaned to remove oxides from the surface. In some embodiments, the oxides are native oxide. In some embodiments, cleaning the surface forms a surface that is substantially free of oxide. As used in this manner, the term “substantially free of oxide” means that there are less than or equal to 5%, 2%, 1% or 0.5% of oxygen atoms on the surface. In one or more embodiments, anisotropic etching is used to remove oxide from the surface.

In one or more embodiments, by combining Mo with Ti in integrated fashion, the contact resistance is reduced more than if there were individual metal silicides. In other words, the combination of Mo and titanium Ti leads to contact resistance, which is lower than with Mo only, and lower than with Ti only, on both the n transistor and on the p transistor.

Referring to FIG. 3, in one or more embodiments, operations 52 and 54 are conducted in an integrated system without vacuum break between operations. In other embodiments, operations 52, 54, 56, and 58 are conducted in an integrated system without vacuum break between operations.

Referring to FIG. 3 and FIG. 4D, at operation 60, a capping layer 370 may be formed on each of the n transistor 302 and the p transistor 304. The capping layer 370 may comprise any suitable material known to the skilled artisan. In one or more embodiments, the capping layer 370 comprises a PVD metal film. In one or more embodiments, the capping layer 370 is selected from one or more of titanium nitride (TiN), tantalum nitride (TaN), tungsten nitride (WN), molybdenum nitride (MoN), PVD tungsten (W), PVD molybdenum (Mo), and PVD ruthenium (Ru). In one or more embodiments, the capping layer 370 prevents formation of oxides on the titanium silicide (TiSi) layer 360.

In additional embodiments, the capping layer 370 is selectively formed on a top surface of titanium silicide (TiSi) layer 360 through the nitridation of the titanium silicide (TiSi) layer 360 by one or more of ammonia (NH₃) plasma, N₂/H₂ plasma, or the like.

Referring to FIG. 3, in some embodiments, at operation 62, optionally annealing the semiconductor structure 300 may further reduce the contact resistance of the structure 300. In one or more embodiments, annealing the semiconductor structure 300 may produce a smooth surface.

The semiconductor structure 300 can be annealed by any process known to a person skilled in the art. In some embodiments, the semiconductor structure is annealed by a rapid thermal process (RTP). In one or more embodiments, the rapid thermal process (RTP) comprises annealing the semiconductor structure 300 to a temperature in a range of about 500° C. to about 700° C. In one or more embodiments, the rapid thermal process (RTP) comprises annealing the semiconductor structure 300 to a temperature of about 600° C.

In some embodiments, the annealed semiconductor structure has a root mean square (RMS) roughness in a range of from 4% to less than 30%, from 4% to less than 20%, from 4% to less than 10%, from 10% to less than 30%, from 10% to less than 20% or from 20% to less than 30%.

With reference to FIG. 3 and FIG. 4E, at operation 64, the first opening 306 over the n transistor 302 and the second opening 308 over the p transistor 304 are independently filled with a gap fill material 380 and a gap fill material 382, respectively. In one or more embodiments, the gap fill material 380 and the gap fill material 382 are substantially free of voids or seams. The gap fill material 380 and the gap fill material 382 may independently comprise any suitable gap fill materials known to the skilled artisan. In one or more embodiments, the gap fill material 380 and the gap fill material 382 independently comprise one or more of tungsten (W), molybdenum (Mo), cobalt (Co), and ruthenium (Ru). In one or more embodiments, the gap fill material 380 in the first opening 306 over the n transistor 302 is the same as the gap fill material 382 in the second opening 308 over the p transistor 304. In one or more embodiments, the gap fill material 380 in the first opening 306 over the n transistor 302 is different than the gap fill material 382 in the second opening 308 over the p transistor 304. In one or more embodiments, the gap fill material 380 and the gap fill material 382 are the same and comprise tungsten (W).

The gap filling process may comprise any suitable gap filling process known to the skilled artisan. In one or more embodiments, the gap filling process comprises exposing the semiconductor structure 300 to a metal precursor and a reactant. In some embodiments, the metal precursor comprises one or more of a molybdenum precursor, a tungsten precursor, a cobalt precursor, and a ruthenium precursor.

In some embodiments, the gap filling process is a bottom-up gap filling process. In other embodiments, the gap filling process comprises a conformal gap filling process.

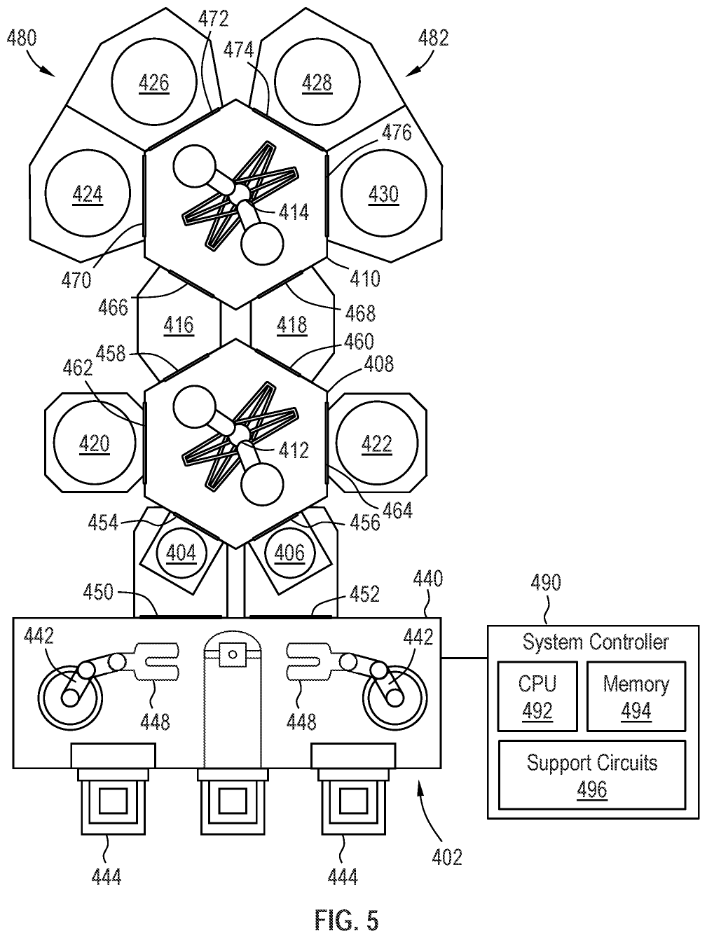

FIG. 5 illustrates a schematic top-view diagram of an example of a multi-chamber processing system 400, or a cluster tool, according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fabrication). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide for an integrated solution for some processing of wafers.

It is contemplated that any suitable processing system known to one of skill in the art may be adapted to benefit from aspects described herein.

In the illustrated example of FIG. 5, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing pre-cleaning process, the processing chamber 422 can be capable of performing a chemical vapor deposition (CVD) process, and the processing chambers 424, 426, 428, 430 can be capable of performing plasma enhanced chemical vapor deposition (PECVD) processes. The processing chamber 420 may be any suitable preclean chamber known to the skilled artisan.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Comparative

A substrate including an n transistor and a p transistor was pre-cleaned, and a layer of titanium silicide was deposited on the junction. A capping layer of PVD tungsten was deposited on the titanium silicide layer, and the contact structure was filled with tungsten.

### Example 2: Comparative

A substrate including an n transistor and a p transistor was pre-cleaned, and a layer of molybdenum silicide was deposited on the junction. A capping layer of PVD tungsten was deposited on the molybdenum silicide layer and the contact structure was filled with tungsten.

### Example 3

A substrate including an n transistor and a p transistor was pre-cleaned. A molybdenum silicide (MoSi) layer was deposited on the p transistor and the n transistor. A titanium silicide (TiSi) layer was formed on the molybdenum silicide (MoSi) layer. A capping layer of PVD tungsten was deposited on the titanium silicide (TiSi) layer and the contact was filled with tungsten.

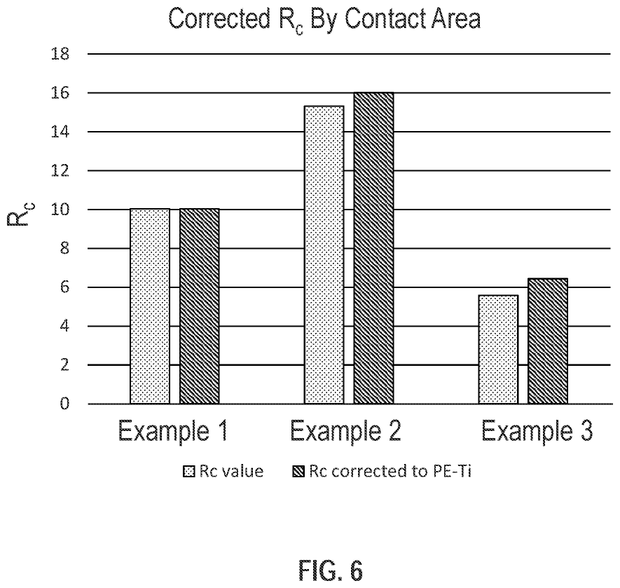

FIG. 6 illustrates the n-transistor contact resistance for the Examples. As shown in FIG. 6, using a combination of MoSi and TiSi (Example 3) produces a device having a reduced contact resistance when compared to a device having titanium silicide alone (Example 1) or molybdenum silicide alone (Example 2).

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor structure, the method comprising:
depositing a molybdenum silicide (MoSi) layer on one or more of a p transistor and an n transistor of a substrate, the substrate comprising an n transistor and the p transistor and having a first opening over the n transistor and a second opening over the p transistor;
optionally, in-situ annealing the substrate in an atmosphere of hydrogen (H₂);
forming a titanium silicide (TiSi) layer on the n transistor and on the p transistor; and
forming a capping layer on the titanium silicide (TiSi) layer.

2. The method of claim 1, further comprising depositing a gap fill material independently in the first opening and in the second opening.

3. The method of claim 1, further comprising pre-cleaning the substrate.

4. The method of claim 3, wherein the method is an integrated method performed in a cluster tool.

5. The method of claim 1, wherein the capping layer comprises one or more of tungsten (W), molybdenum (Mo), ruthenium (Ru), titanium nitride (TiN), tantalum nitride (TaN), and tungsten nitride (WN).

6. The method of claim 1, wherein the n transistor comprises silicon (Si) doped with phosphorous (P), and the p transistor comprises silicon germanium (SiGe) doped with boron (B).

7. The method of claim 2, wherein the gap fill material is substantially free of voids or seams.

8. The method of claim 2, wherein the gap fill material comprises one or more of tungsten (W), molybdenum (Mo), cobalt (Co), and ruthenium (Ru).

9. The method of claim 4, wherein the method results in a contact resistance that is lower than a contact resistance of a p transistor or an n transistor comprising molybdenum silicide alone.

10. The method of claim 4, wherein the method results in a contact resistance that is lower than a contact resistance of a p transistor or an n transistor comprising titanium silicide alone.

11. The method of claim 1, wherein the molybdenum silicide (MoSi) layer is on both the n transistor and on the p transistor.

12. A method of forming a semiconductor structure, the method comprising:
pre-cleaning a substrate, the substrate comprising an n transistor and a p transistor, a first opening over the n transistor and a second opening over the p transistor;
depositing a molybdenum silicide (MoSi) layer on the p and on the n transistor;
optionally, in-situ annealing the substrate in an atmosphere of hydrogen (H₂);
forming a titanium silicide (TiSi) layer on the molybdenum silicide (MoSi) layer;
forming a capping layer on the titanium silicide (TiSi) layer; and
depositing a gap fill material in the first opening and in the second opening.

13. The method of claim 12, wherein the capping layer comprises one or more of tungsten (W), molybdenum (Mo), ruthenium (Ru), titanium nitride (TiN), tantalum nitride (TaN), and tungsten nitride (WN).

14. The method of claim 12, wherein the gap fill material comprises one or more of tungsten (W), molybdenum (Mo), cobalt (Co), and ruthenium (Ru).

15. The method of claim 12, wherein the n transistor comprises silicon (Si) doped with phosphorous (P), and the p transistor comprises silicon germanium (SiGe) doped with boron (B).

16. The method of claim 12, wherein the gap fill material is substantially free of voids or seams.

17. The method of claim 12, wherein the method results in a contact resistance that is lower than a contact resistance of a p transistor or an n transistor comprising molybdenum silicide alone.

18. The method of claim 12, wherein the method results in a contact resistance that is lower than a contact resistance of a p transistor or an n transistor comprising titanium silicide alone.

19. A semiconductor structure comprising:
an n transistor and a p transistor;
a molybdenum silicide (MoSi) layer on one or more of the p transistor and the n transistor;
a titanium silicide (TiSi) layer on the p transistor and on the n transistor;
a capping layer on the titanium silicide (TiSi) layer; and
a gap fill material.

20. The semiconductor structure of claim 19, wherein the molybdenum silicide (MoSi) layer is on both the n transistor and the p transistor.
